(19) United States
(12) Patent Application Publication
(10) Pub. No.: US 2014/0367707 A1
(43) Pub. Date: Dec. 18, 2014

(54) DISPLAY PANEL AND MANUFACTURING METHOD THEREOF

(71) Applicant: E Ink Holdings Inc., Hsinchu (TW)

(72) Inventors: Hsin-Fei Meng, Hsinchu (TW); Wen-Syang Hsu, Hsinchu (TW); Hsiao-Wen Zan, Hsinchu (TW); Yu-Hsin Lin, Hsinchu (TW); Chuang-Chuang Tsai, Hsinchu (TW); Cheng-Hang Hsu, Hsinchu (TW); Kai-Cheng Chuang, Hsinchu (TW)

(73) Assignee: E Ink Holdings Inc., Hsinchu (TW)

(21) Appl. No.: 14/191,466

(22) Filed: Feb. 27, 2014

(30) Foreign Application Priority Data
Jun. 14, 2013 (TW) 102121158

(51) Int. Cl. H01L 51/56; H01L 27/32

(52) U.S. Cl. CPC H01L 51/56; H01L 27/3244
USPC 257/88; 438/23

(57) ABSTRACT

A manufacturing method of a display panel including following steps is provided. An active device substrate including a first plate, active devices disposed on the first plate and pixel electrodes electrically connected to the active devices is provided. A display medium substrate including a second plate and a display medium disposed on the second plate is provided. The pixel electrodes are electrically connected to the display medium by a conductor. Moreover, a display panel manufactured by the manufacturing method is also provided.

### CROSS-REFERENCE TO RELATED APPLICATION

This application claims the priority benefit of Taiwan application serial no. 102121158, filed on Jun. 14, 2013. The entirety of the above-mentioned patent application is hereby incorporated by reference herein and made a part of this specification.

### BACKGROUND

1. Field of the Invention

The present invention is directed to an optoelectronic element and a manufacturing method thereof and more particularly to a display panel and a manufacturing method thereof.

2. Description of Related Art

In the conventional manufacturing process of a display panel, a display medium layer is manufactured after active devices. Therefore, in some manufacturing processes of the display medium layer (e.g. an organic light-emitting diode (OLED) layer), the temperature of the manufacturing process of the display medium layer would cause damages to the active devices. In order to avoid such a problem, the active devices generally adopt switching elements which are not sensitive to the temperature, such as inorganic thin film transistors. However, the inorganic thin film transistors have bad flexibility and are not easy for manufacturing a flexible display panel.

### SUMMARY

The present invention provides a manufacturing method, and a display panel manufactured by the manufacturing method has good performance.

The present invention provides a display panel with good performance.

The present invention provides a manufacturing method of a display panel and the method provides the following steps. An active device substrate is provided, wherein the active device substrate includes a first plate, a plurality of active devices disposed on the first plate and a plurality of pixel electrodes electrically connected to the plurality of active devices. A display medium substrate is provided, where the display medium substrate includes a second plate and a display medium layer disposed on the second plate. The pixel electrodes are electrically connected with the display medium layer by using the conductive material.

The present invention provides a display panel including the active device substrate, the display medium substrate and the conductive material. The conductive material is disposed between the display medium layer and the pixel electrodes and electrically connected with the pixel electrodes and the display medium layer.

In an embodiment of the present invention, the display medium substrate further includes a plurality of connection electrodes corresponding to the pixel electrodes and is located between the second plate and the connection electrodes.

In an embodiment of the present invention, the step of electrically connecting the plurality of pixel electrodes with the display medium layer by using the conductive material includes distributing the conductive particles on the pixel electrodes and electrically insulating at least one conductive particle of the conductive particles distributed on the same pixel electrode from the other conductive particles, heating the conductive particles and contacting each of the connection electrodes with the at least one conductive particle on the corresponding pixel electrodes.

In an embodiment of the present invention, the step of distributing the conductive particles on the pixel electrodes and electrically insulating at least one conductive particle of the conductive particles distributed on the same pixel electrode from the other conductive particles includes providing a mask, wherein the shielding mask has a shielding portion and a plurality of through holes penetrating through the shielding portion, exposing the pixel electrodes respectively from the through holes of the mask, shielding a region between the pixel electrodes by the shielding portion of the mask, penetrating the conductive particles through the through holes by using the shielding mask and distributing the same on the pixel electrodes.

In an embodiment of the present invention, before the step of distributing the conductive particles on the pixel electrodes, the manufacturing method of the display panel further includes a step of forming a plurality of adhesive patterns on the pixel electrodes, and the step of distributing the conductive particles of the pixel electrodes includes fastening the conductive particles on the pixel electrodes through the adhesive patterns.

In an embodiment of the present invention, a material of the adhesive patterns is flux.

In an embodiment of the present invention, the step of electrically connecting the plurality of pixel electrodes with the display medium layer by using the conductive material includes distributing the conductive particles on the connection electrodes and electrically insulating at least one conductive particle of the conductive particles distributed on the same connection electrode from the other conductive particles, heating the conductive particles and contacting of contacting each of the connection electrodes with the at least one conductive particle on the corresponding connection electrode.

In an embodiment of the present invention, the step of distributing the conductive particles on the connection electrodes and electrically insulating at least one conductive particle of the conductive particles distributed on the same connection electrode from the other conductive particles includes providing a mask, exposing the connection electrodes respectively from the through holes of the mask, shielding a region between the connection electrodes by the shielding portion of the shielding mask and penetrating the conductive particles through the through holes by using the shielding mask and distributing the same on the connection electrodes.

In an embodiment of the present invention, before the step of distributing the conductive particles on the connection electrodes, the manufacturing method of the display panel further includes a step of foaming a plurality of adhesive patterns on the connection electrodes, and the step of distributing the conductive particles on the connection electrodes includes fastening the conductive particles on the connection electrodes through the adhesive patterns.

In an embodiment of the present invention, a size of each of the conductive particles is larger than a maximum change of a thickness of the active device substrate or a maximum change of a thickness of display medium substrate.

In an embodiment of the present invention, the active device substrate further includes a first insulation pattern layer. The first insulation pattern layer exposes the pixel electrodes and covers the region between the pixel electrodes in the first plate. The display medium substrate further includes a second insulation pattern layer. The second insulation pattern layer exposes the connection electrodes and covers a region between the second plate and the connection electrodes.

In an embodiment of the present invention, the step of electrically connecting the pixel electrodes with the display medium layer by using the conductive material includes distributing the conductive particles on one of the plurality of pixel electrodes and the plurality of connection electrodes, heating the conductive particles, contacting the other one of the plurality of pixel electrodes and the plurality of connection electrodes with the conductive particles.

In an embodiment of the present invention, the conductive material is an anisotropic conductive film (ACF).

In an embodiment of the present invention, the step of electrically connecting the pixel electrodes with the display medium layer by using the conductive material includes forming the ACF on one of the plurality of pixel electrodes and the display medium layer connecting the other one of the plurality of pixel electrodes and the display medium layer with the ACF.

In an embodiment of the present invention, before the step of electrically connecting the plurality of pixel electrodes with the display medium layer by using the conductive material, the manufacturing method of the display panel further includes a step of forming a plurality of gap maintaining structures on the active device substrate or the display medium substrate.

In an embodiment of the present invention, before the step of electrically connecting the plurality of pixel electrodes with the display medium layer by using the conductive material, the manufacturing method of the display panel further includes a step of performing an annealing process on the active device substrate.

In an embodiment of the present invention, the conductive particles contact the connection electrodes and the pixel electrodes.

In an embodiment of the present invention, the conductive particles are distributed on a region where the pixel electrodes overlap the connection electrodes, but neither distributed on a region between the pixel electrodes nor a region between the connection electrodes.

In an embodiment of the present invention, the pixel electrodes are located between the first insulation pattern layer and the first plate, and the connection electrodes are located between the second plate and the second insulation pattern layer.

In an embodiment of the present invention, the ACF contacts the connection electrodes, the display medium layer and the pixel electrodes.

In an embodiment of the present invention, the ACF contacts the display medium layer and the pixel electrodes.

In an embodiment of the present invention, the display panel further includes a plurality of gap maintaining structures disposed between the active device substrate and the display medium substrate.

In an embodiment of the present invention, the display medium substrate further includes a common electrode located between the second plate and the display medium layer.

In an embodiment of the present invention, the pixel electrodes are reflective electrodes, the common electrode is a transparent electrode, and the second plate is a transparent substrate.

In an embodiment of the present invention, the pixel electrodes are reflective electrodes, and the second plate is a transparent substrate.

Based on the above, in the manufacturing method of the display panel and the display panel manufactured thereby according an embodiment of the present invention, the active devices and the display medium layer are connected with each other only after the first plate and the second plate are respectively manufactured. Thus, a temperature during a process of manufacturing the display medium layer neither causes bad impact on the active devices nor impact performance of the display panel. In addition, the pixel electrodes are electrically connected with the display medium layer by using the conductive material, and thus, resistivity between the pixel electrodes and the display medium layer is small, such that the display panel may have good performance.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the present invention, and are incorporated in and constitute a part of this specification. The drawings illustrate embodiments of the present invention and, together with the description, serve to explain the principles of the present invention.

FIG. 1A through FIG. 1G are cross-sectional schematic diagrams illustrating a manufacturing process of a display panel according to an embodiment of the present invention.

FIG. 2A through FIG. 2E are cross-sectional schematic diagrams illustrating a manufacturing process of a display panel according to another embodiment of the present invention.

FIG. 3 illustrates detailed structures in part of a region of the active device substrate depicted in FIG. 1G.

FIG. 4 illustrates detailed structures in part of a region of the display medium substrate depicted in FIG. 1G.

FIG. 5 illustrates detailed structures in part of a region of a display medium substrate according to an embodiment of the present invention.

FIG. 6 illustrates detailed structures in part of a region of a display medium substrate according to an embodiment of the present invention.

FIG. 7A through FIG. 7D are cross-sectional schematic diagrams illustrating a manufacturing process of a display panel according to an embodiment of the present invention.

FIG. 8 is a cross-sectional schematic diagram illustrating a manufacturing process of a display panel according to an embodiment of the present invention.

FIG. 9 is a cross-sectional schematic diagram illustrating a manufacturing process of a display panel according to an embodiment of the present invention.

### DESCRIPTION OF EMBODIMENTS

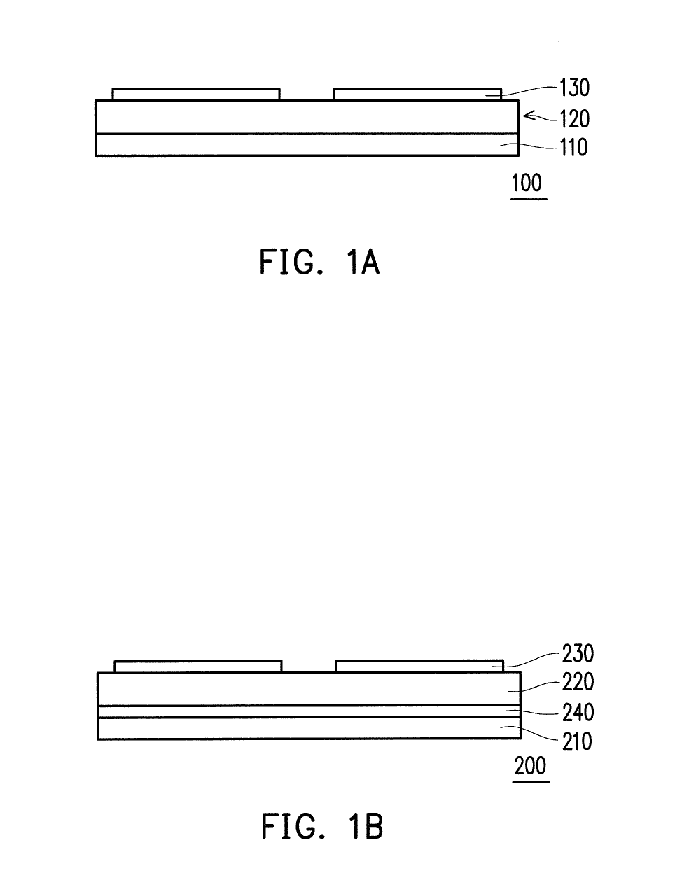

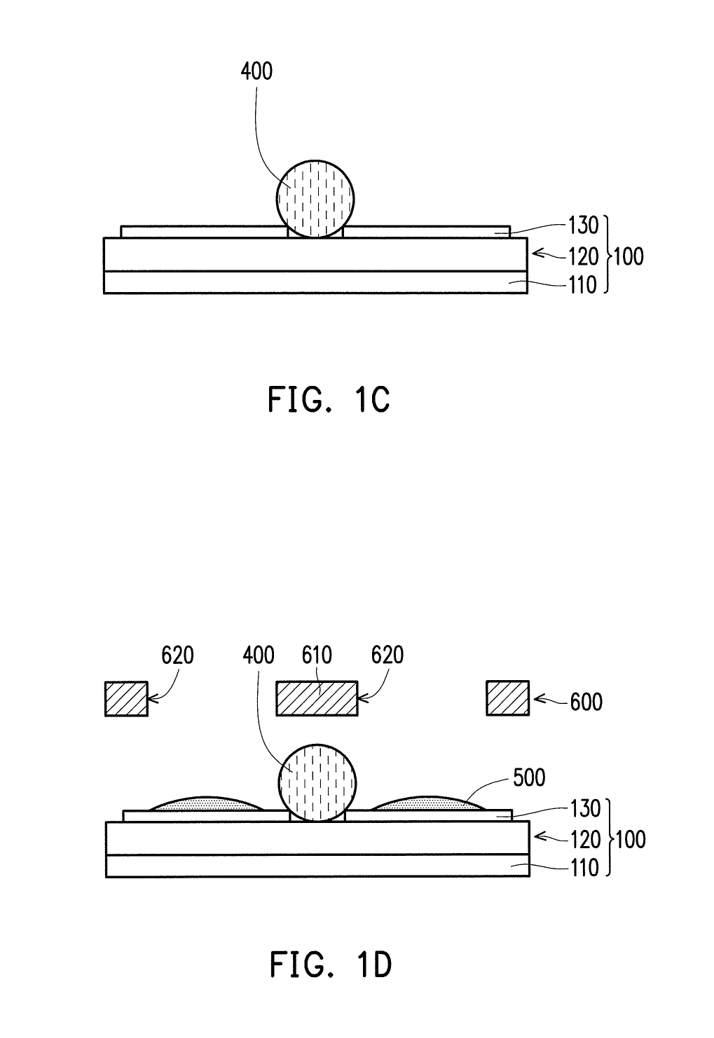

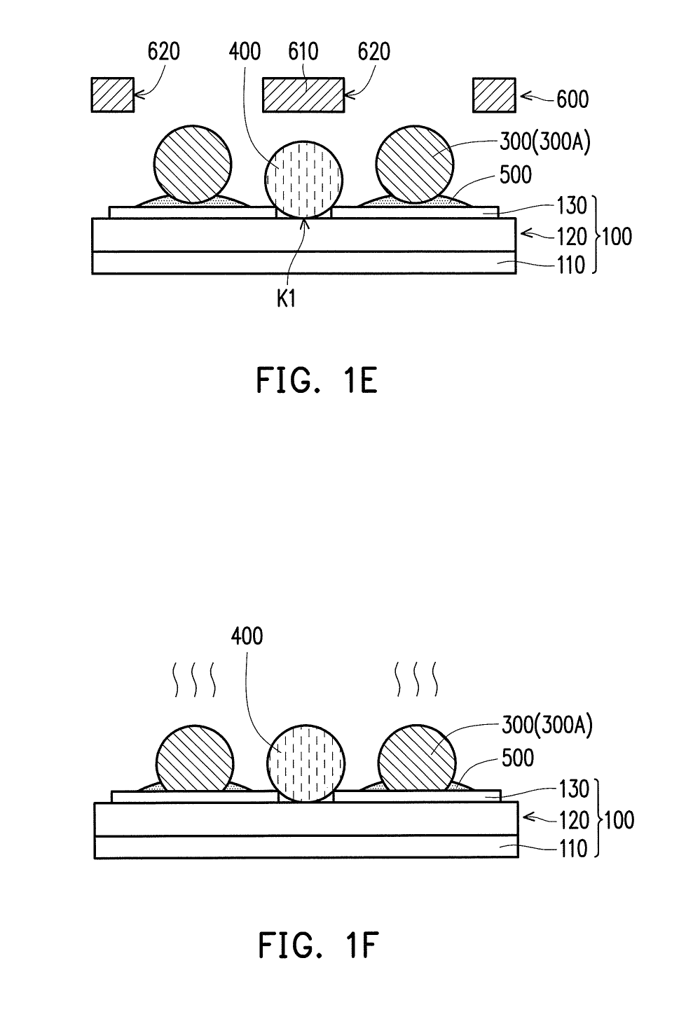

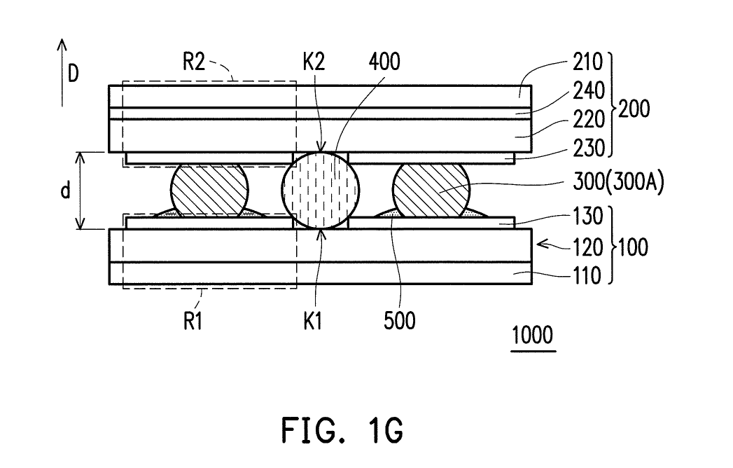

FIG. 1A through FIG. 1G are cross-sectional schematic diagrams illustrating a manufacturing process of a display panel according to an embodiment of the present invention. Referring to FIG. 1A and FIG. 1B, first, an active device substrate 100 and a display medium substrate 200 are provided. In the present embodiment, the active device substrate 100 and the display medium substrate 200 are respectively manufactured. As illustrated in FIG. 1A, the active device substrate 100 includes a first plate 110, a plurality of active devices 120 disposed on the first plate 110 and a plurality of pixel electrodes 130 electrically connected with the active devices 120. The pixel electrodes 130 are separated from each other. As illustrated in FIG. 1B, the display medium substrate 200 includes a second plate 210 and a display medium layer 220 disposed on the second plate 210. In the present embodiment, display medium substrate 200 further includes a plurality of connection electrodes 230 corresponding to the pixel electrodes 130. The connection electrodes 230 are separated from each other. The display medium layer 220 is located between the second plate 210 and the connection electrodes 230.

Referring to FIG. 1C through FIG. 1G, then the pixel electrodes 130 are electrically connected with the display medium layer 220 by using a conductive material 300. It is to be noticed that with reference to FIG. 1G, the active device substrate 100 is stacked on the display medium substrate 200 in a stacking direction, and in the stacking direction D, the pixel electrodes 130 are conducted on with a portion of the display medium layer 220 thereon by using the conductive material 300. However, in the stacking direction D, neither any two of the pixel electrodes 130 are conducted with each other by using the conductive material 300, nor each of the pixel electrodes 130 are conducted on with the other portion of the connection electrodes 230 that are not corresponding to the pixel electrodes 130 by using the conductive material 300.

To be detailed, in the present embodiment, when the conductive material 300 includes a plurality of conductive particles 300A, the aforementioned process of electrically connecting the pixel electrodes 130 with the display medium layer 220 by using the conductive material 300 includes the following steps.

Referring to FIG. 1E, the conductive particles 300A may be distributed on the pixel electrodes 130, and at least one of the conductive particles 300A distributed on the same pixel electrode 130 is electrically insulated from the other conductive particles 300A. To be more specific, a shielding mask 600 may be provided. The shielding mask 600 has a shielding portion 610 and a plurality of through holes 620 penetrating through the shielding portion 610. Then, the through holes 620 of the shielding mask 600 respectively expose the pixel electrodes 130, and the shielding portion 610 of the shielding mask 600 shields a region K1 between the pixel electrodes 130. Afterward, the conductive particles 300A penetrate through the through holes 620 by using the shielding mask 600 as a mask so as to be disturbed on the pixel electrodes 130. In the present embodiment, the shielding portion 610 of the shielding mask 600 shields the region between the pixel electrodes 130, and thus, the conductive particles 300A do not easily fall within the region K1 between the pixel electrodes 130, and thereby, a short-circuit problem between the pixel electrodes 130 is prevented.

In the present embodiment, in order to distribute the conductive particles 300A on the pixel electrodes 130 better, referring to FIG. 1D, a plurality of adhesive patterns 500 may be formed on the pixel electrodes 130 before distributing the conductive particles 300A on the pixel electrodes 130. In particular, the through holes 620 of the shielding mask 600 may respectively expose the pixel electrodes 130, while the shielding portion 610 of the shielding mask 600 shields the region between the pixel electrodes 130. Then, by using the shielding mask 600 as a mask, an adherent material may pass through the through holes 620, and as such, the plurality of adhesive patterns 500 are formed on the pixel electrodes 13. Accordingly, when the conductive particles 300A penetrate through the through holes 620, the conductive particles 300A may be temporarily fastened on the pixel electrodes 130 through the adhesive patterns 500. In the present embodiment, the conductive particles 300A may be, for example, tin balls, and a material of the adhesive patterns 500 may be, for example, flux. The adhesive patterns 500 made of the material of flux may not only temporarily fasten the conductive particles 300A but also clean surfaces of the pixel electrodes 130, such that the conductive particles 300A may be electrically connected with the pixel electrodes 130 better.

Referring to FIG. 1F, after distributing the conductive particles 300A on the pixel electrodes 130, the conductive particles 300A is heated, such that the conductive particles 300A are in a melted state (i.e., a liquid state). In particular, the conductive particles 300A may be heated by using a hot air gun. However, the present invention is not intent to limit the way to heat the conductive particles 300A, and in other embodiments, the conductive particles 300A may be heated by adopting other adaptive ways. It should be noticed that a conductive material with a low melting point may be selected for the conductive particles 300A, such that the active devices 120 would not easily damaged by the temperature during a process for melting the conductive particles 300A. For example, the conductive particles 300A may be tin-bismuth alloy ball with a melting point of 139° C., and the conductive particles 300A may be heated by using a hot air gun with a temperature set to 150° C. for 5 minutes. Since the temperature for heating the conductive particles 300A is low and the time for heating the conductive particles 300A is short, and thus, the active devices 120 are not easily damaged during the process of heating the conductive particles 300A.

Additionally, in the present embodiment, before heating the conductive particles 300A, an annealing process is performed on the active device substrate 100, and conditions of the annealing process may be, for example, 150° C. and for 5 minutes. The annealing process may stabilize the electricity of the active devices 120, such that the electricity of the active devices 120 would not be changed easily during the process of heating the conductive particles 300A.

Referring to FIG. 1G, then, the display medium substrate 200 is placed on the conductive particles 300A when the conductive particles 300A are not completely transferred from a liquid state to a solid state, such that each of the connection electrodes 230 of the display medium substrate 200 contacts at least one conductive particle 300A on the corresponding pixel electrodes 130. As such, when the temperature of the conductive particles 300A is lowered down to below the melting point of the conductive particles 300A, each of the connection electrodes 230 may be fixedly connected and conducted on with the corresponding pixel electrodes 130 so as to take the places of functions of the pixel electrodes 130 to drive the display medium layer 220. Up to this step, a display panel 1000 is initially finished.

It is to be mentioned that the active devices 120 and the display medium layer 220 start to be electrically connected with each other by using the conductive material 300 after the first plate 110 and the second plate 210 are respectively manufactured. Thus, the process temperature of the display medium layer 220 would not cause bad impact on the active devices 120 to impact the performance of the display panel 1000. Additionally, each of the pixel electrodes 130 is electrically connected with part of the display medium layer 220 thereabove through the conductive material 300, and thus, resistivity between each of the pixel electrodes 130 and the part of the display medium layer 220 thereabove is small, such that the display panel 1000 has good performance.

Moreover, in the present embodiment, in order electrically connect each of the pixel electrodes 130 with the corresponding connection electrodes 230 better, a size of the conductive particles 300A may be larger than a maximum change of a thickness of the active device substrate 100. By doing so, when the display medium layer 220 and the pixel electrodes 130 are about to be electrically connected, the conductive particles 300A may compensate height difference between each of the pixel electrodes 130, such that each of the connection electrodes 230 may be electrically connected with the corresponding pixel electrodes 130 well.

Besides, in the present embodiment, in order to keep a distance d (as shown in FIG. 1G) between the active device substrate 100 and the display medium substrate 200 in consistence, referring to FIG. 1C, a plurality of gap maintaining structures 400 may be formed on the active device substrate 100 before electrically connecting the pixel electrodes 130 and the display medium layer 220 by using the conductive material 300. In the present embodiment, a method for forming the gap maintaining structures 400 may be spraying the gap maintaining structures 400, such as ball spacers (BS), on the active device substrate 100, but the present invention is not limited thereto. In other embodiments, the method may be forming a film (e.g. a photoresist layer) on the active device substrate 100 and then patterning the film to form a plurality of gap maintaining structures 400, such photo spacers (PS). Thereby, when the connection electrodes 230 of the display medium substrate 200 is to be correspondingly connected with the pixel electrodes 130 of the active device substrate 100, the gap maintaining structures 400 formed on the display medium substrate 200 may achieve the function of keeping the distance d in consistence. When the active device substrate 100 and the display medium substrate 200 are flexible substrates, the structural strength of a display may be enhanced.

In the embodiment illustrated in FIG. 1A through FIG. 1G, the connection electrodes 230 of the display medium substrate 200 contacts the conductive particles 300A only after the conductive particles 300A are heated. However, the present invention is not limited thereto. In other embodiments, if the active devices 120 and the display medium layer 220 are capable of tolerating the temperature for heating the conductive particles 300A, the conductive particles 300A may first contact the pixel electrodes 130 of the active device substrate 100 and the connection electrodes 230 of the display medium substrate 200. Namely, the conductive particles 300A, the active device substrate 100 and the display medium substrate 200 may be first configured at the relative positions as illustrated in FIG. 1G, and the conductive particles 300A may be then heated, such that each of the connection electrodes 230 may be fixedly connected and conducted on with the corresponding pixel electrodes 130.

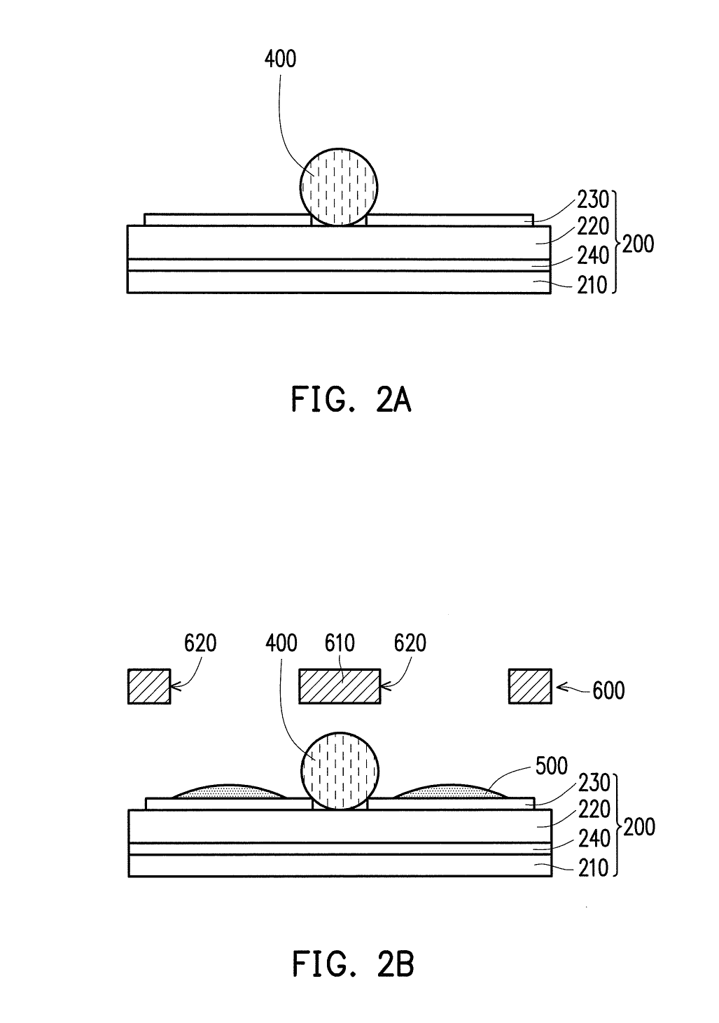

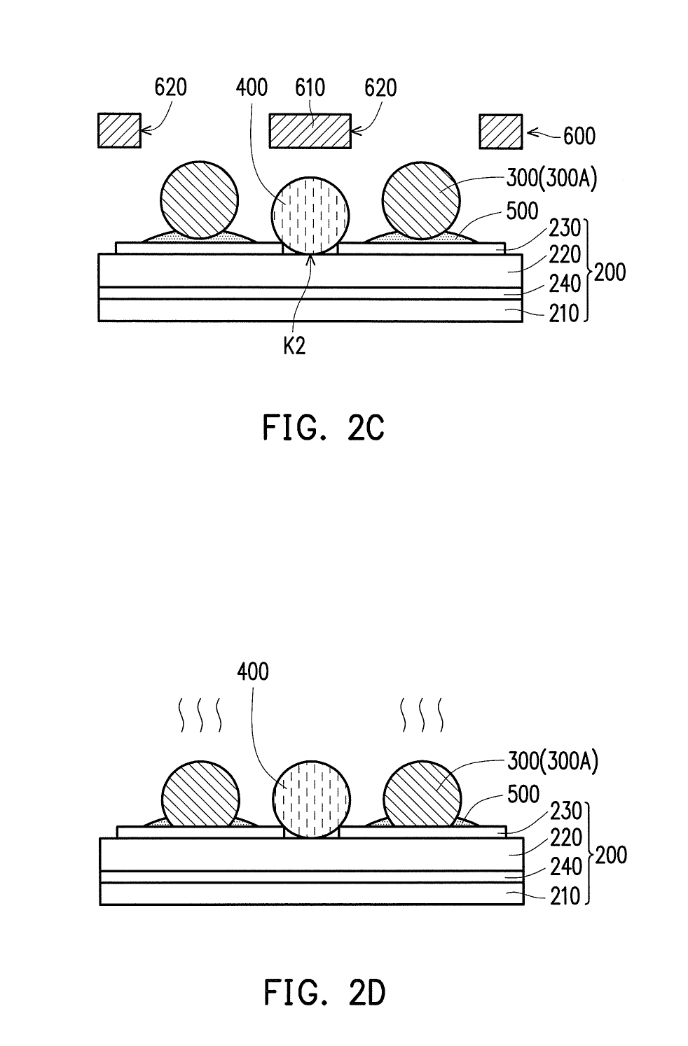

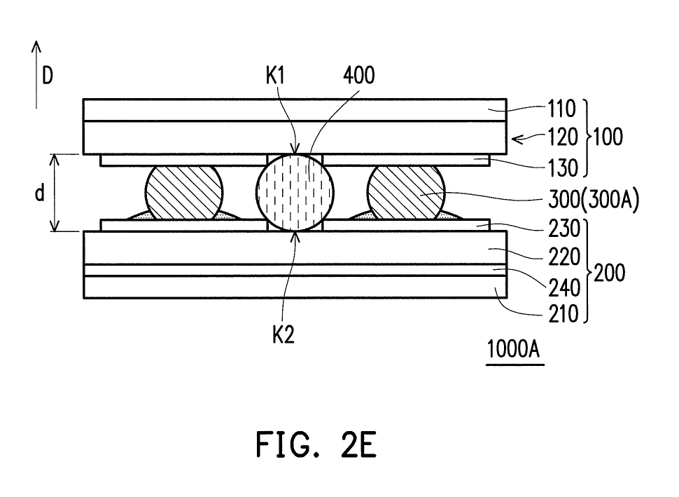

In the embodiment illustrated in FIG. 1A through FIG. 1G, the conductive particles 300A are first distributed on the pixel electrodes 130 of the active device substrate 100 and then electrically connected with the connection electrodes 230 of the display medium substrate 200. However, the present invention is not limited thereto. In other embodiments, if the display medium layer 220 has good thermal resistance, the conductive particles 300A may also be first distributed on the connection electrodes 230 of the display medium substrate 200 and then electrically connected with the pixel electrodes 130 of the active device substrate 100, which will be specifically described with reference to FIG. 2A through FIG. 2E hereinafter.

FIG. 2A through FIG. 2E are cross-sectional schematic diagrams illustrating a manufacturing process of a display panel according to another embodiment of the present invention. The manufacturing process of the display panel illustrated in FIG. 2A through FIG. 2E is similar to that illustrated in FIG. 1A through FIG. 1G, and thus, the same elements are labeled by the same or corresponding reference numerals. Referring to FIG. 2C, after respectively manufacturing the active device substrate 100 and the display medium substrate 200, the conductive particles 300A may be distributed on the connection electrodes 230, and at least one conductive particle 300A distributed on the same connection electrode 230 is electrically insulated from the other conductive particles 300A.

To be more specific, a shielding mask 600 may be provided. Then, the through holes 620 of the shielding mask 600 respectively expose the connection electrodes 230 and the shielding portion 610 of the shielding mask 600 shields a region K2 between the connection electrodes 230. By using the shielding mask 600 as a mask, the conductive particles 300A penetrate through the through holes 620 so as to be distributed on the connection electrodes 230. In the present embodiment, the shielding portion 610 of the shielding mask 600 shields the region K2 between the connection electrodes 230, and thus, the conductive particles 300A do not easily fall within the region K2 between the connection electrodes 230, and thereby, a short-circuit problem between the connection electrodes 230 is prevented.

Similarly, in the present embodiment, in order to electrically connect each of the pixel electrodes 130 with the corresponding connection electrode 230 better, a size of the conductive particles 300A may be larger than a maximum change of a thickness of the display medium substrate 200. By doing so, when the connection electrodes 230 are about to be electrically connected with the pixel electrodes 130 in a follow-up step, the conductive particles 300A may compensate height difference between the connection electrodes 230, such that each of the pixel electrodes 130 may be electrically connected with the corresponding connection electrode 230 well. Additionally, in the present embodiment, in order to keep the distance d between the active device substrate 100 and the display medium substrate 200 in consistence, referring to FIG. 2A, the plurality of gap maintaining structures 400 may be formed on the display medium substrate 200 before the pixel electrodes 130 are electrically connected with the display medium layer 220 by using the conductive material 300. Similarly, in the present embodiment, the method for forming the gap maintaining structures 400 may be spraying the gap maintaining structures 400, such as the ball spacers, on the display medium substrate 200, but the present invention is not limited thereto. In other embodiments, the method may be foaming a film (e.g. a photoresist layer) on the display medium substrate 200 and then patterning the film to form a plurality of gap maintaining structures 400, such the photo spacers (PS).

Referring to FIG. 2D, after the conductive particles 300A are distributed on the connection electrodes 230, the conductive particles 300A may be heated, so that the conductive particles 300A are in the melted state (i.e., the liquid state). Referring to FIG. 2E, then, when the conductive particles 300A are not completely transferred from the liquid state to the solid state, the active device substrate 100 is placed on the conductive particles 300A, such that each of the pixel electrodes 130 of the active device substrate 100 contacts at least one conductive particle 300A on the corresponding connection electrode 230. Thereby, when the temperature of the conductive particles 300A is lowered down to below the melting point of the conductive particles 300A, each of the connection electrodes 230 may be fixedly connected and conducted on with the corresponding pixel electrode 130. Up to this step, a display panel display panel 1000A is initially finished.

The display panel 1000A manufactured by the manufacturing method illustrated in FIG. 2A through FIG. 2E has the same structure of the display panel 1000 manufactured by the manufacturing method illustrated in FIG. 1A through FIG. 1G. Therefore, taking the display panel 1000 illustrated in FIG. 1G for example, a structure of a display panel according to an embodiment of the present invention will be described, and the structure of the display panel 1000A will no longer be repeated.

Referring to FIG. 1G, the display panel 1000 includes an active device substrate 100 and a display medium substrate 200 opposite to the active device substrate 100. A display medium layer 220 of the display medium substrate 200 is located between the second plate 210 and the pixel electrodes 130. Particularly, the display panel 1000 further includes a conductive material 300 disposed between the display medium layer 220 and the pixel electrodes 130. The conductive material 300 is electrically connected with the pixel electrodes 130 and the display medium layer 220. Moreover, in the present embodiment, the conductive material 300 is electrically connected with the pixel electrodes 130 and the display medium layer 220 through the connection electrodes 230. A material of the first plate 110 and the second plate 110 may be selected from a rigid material (e.g. glass), a flexible material (e.g. plastic) or a combination thereof. In other words, the display panel 1000 of the present embodiment may be a rigid display panel or a flexible display panel.

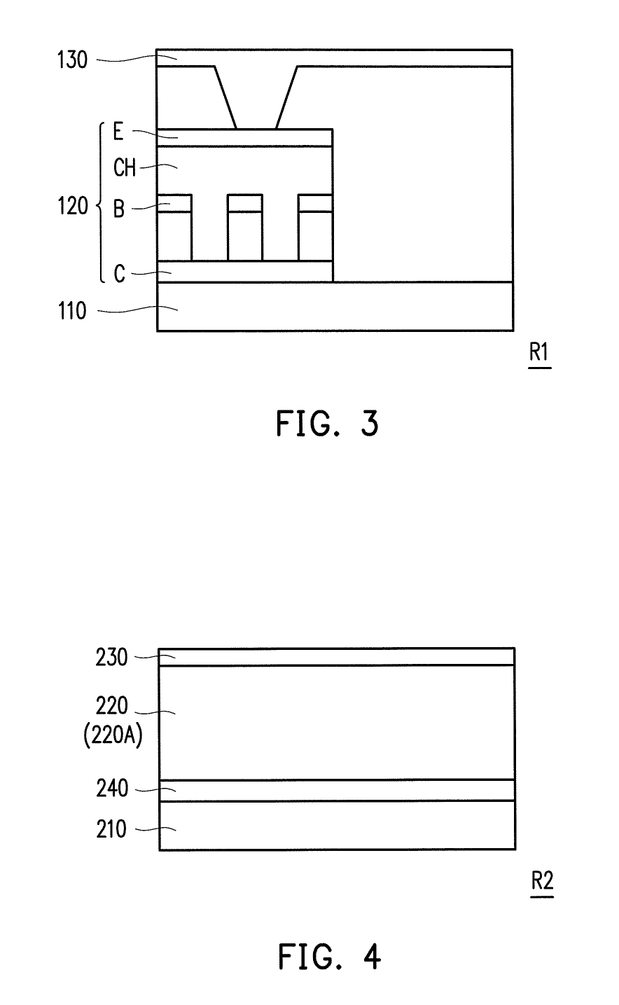

FIG. 3 illustrates detailed structures in part of a region R1 of the active device substrate depicted in FIG. 1G. Referring to FIG. 1G and FIG. 3, in the present embodiment, the active devices 120 may be space current limited transistors (SCLTs). An SCLT includes an emitter E, an organic film CH, a base B and a collector C. The emitter E, the organic film CH, the base B and the collector C may e arranged in sequence in a direction adjacent to the first plate 110. The pixel electrodes 130 are electrically connected with emitter E of the active devices 120. However, the active devices of the present invention are not limited to the form of being the SCLTs, while in other embodiments, the active devices may any other adaptive form of switching elements, such as bottom gate thin film transistors (bottom gate TFTs) or top gate TFTs.

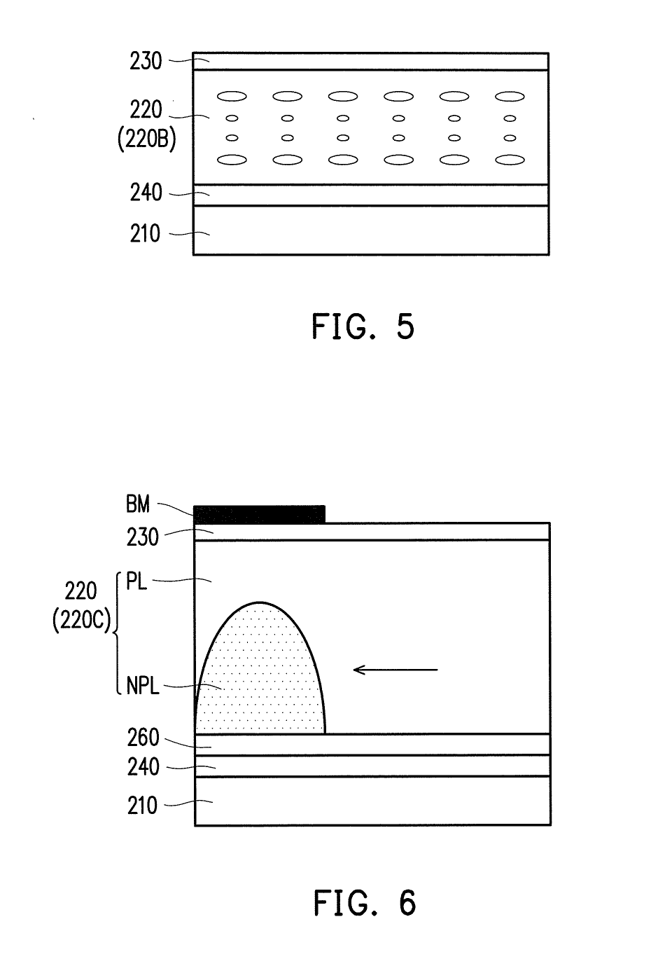

FIG. 4 illustrates detailed structures in part of a region R2 of the display medium substrate depicted in FIG. 1G. Referring to FIG. 1G and FIG. 4, in the present embodiment, the display medium layer 220 may be an organic light-emitting layer 220A, such as an organic light emitting diode (OLED) layer. The display medium substrate 200 further includes a common electrode 240 located between the second plate 210 and the display medium layer 220. The common electrode 240 may overall cover a region used for displaying in the second plate 210. The organic light-emitting layer 220A is sandwiched between the connection electrodes 230 and the common electrode 240. The connection electrodes 230 may take the places of functions of the pixel electrodes 130 to drive the organic light-emitting layer 220A together with the common electrode 240 and thereby, the display panel 1000 may display images. However, the display medium layer of the present invention is not limited to the aspect of the organic light-emitting layer, and in other embodiments, the display medium layer 220 may have other adaptive aspects, which will be described with reference to examples illustrated in FIG. 5 and FIG. 6.

FIG. 5 illustrates detailed structures in part of a region of a display medium substrate according to an embodiment of the present invention. Specially, the part of the region of the display medium substrate in FIG. 5 corresponds to the part of the region R2 illustrated in FIG. 1G. Referring to FIG. 5, in another embodiment of the present invention, the display medium layer 220 may also be a liquid crystal layer 220B, such as a cholesteric liquid crystal layer. The connection electrodes 230 together with the common electrode 240 may drive the liquid crystal layer 220B, such that the display panel 1000 may display images. It is to be described that in other embodiments, the common electrode 240 does not have to be disposed on the display medium substrate 200 and may also be disposed on the active device substrate 100. For instance, if the display medium layer 220 is a liquid crystal layer adaptive for a FFS fringe field switching (FFS-mode) or a in-plane switching (IPS-mode) display panel, the common electrode 240 may also be disposed on the active device substrate 100. In other words, shape and disposed position of the common electrode 240 may be adaptively adjusted depending on the form of the display medium layer 220.

FIG. 6 illustrates detailed structures in part of a region of a display medium substrate according to an embodiment of the present invention. Specially, the part of the region of the display medium substrate in FIG. 6 corresponds to the part of the region R2 illustrated in FIG. 1G. Referring to FIG. 6, in another embodiment of the present invention, the display medium layer 220 may also be an electro-wetting liquid layer 220C. The connection electrodes 230 together with the common electrode 240 may drive the electro-wetting liquid layer 220C. In detail, the electro-wetting liquid layer 220C may include a polar liquid PL and non-polar liquid NPL. A hydrophobic layer 260 may be disposed between the electro-wetting liquid layer 220C and the common electrode 240. A user may view the display panel 1000 from the second plate 210 end. A shielding pattern BM is disposed on the connection electrodes 230. However, the present invention is not limited thereto. In other embodiments, the shielding pattern BM may also be disposed between the second plate 210 and the common electrode 240 or between the common electrode 240 and the hydrophobic layer 260. In a scenario where a voltage is not applied to the connection electrodes 230 and the common electrode 240, the hydrophobic layer 260 may have smaller affinity force relative to surface tension of the polar liquid PL, so as to be uneasily attached to the polar liquid PL but easily attached to the non-polar liquid NPL. As such, the non-polar liquid NPL may dispersive cover the hydrophobic layer 260. When light emits into the electro-wetting liquid layer 220C, part or all of the light are absorbed by the dispersive non-polar liquid NPL to present colors of the non-polar liquid NPL. In another scenario where a voltage is applied to the connection electrodes 230 and the common electrode 240, a dielectric characteristic of the hydrophobic layer 260 is changed by the influence from an electric field between the connection electrodes 230 and the common electrode 240 and so is a surface characteristic thereof, and as result, the hydrophobic layer 260 may turn to have a greater affinity force to the polar liquid PL. Therefore, under a scenario of being powered on, the polar liquid PL is attracted by the hydrophobic layer 260 having a changed surface energy and moved, such that the non-polar liquid NPL is pushed to display other colors. With the aforementioned operation method, the electro-wetting liquid layer 220C may facilitate the display panel 1000 in displaying images.

Referring to FIG. 1G again, in the present embodiment, the conductive material 300 may be a plurality of conductive particles 300A. The display medium substrate 200 further includes a plurality of connection electrodes 230, where the connection electrodes 230 correspond to the pixel electrodes 130. In particular, each of the connection electrodes 230 may overlap one pixel electrode 130 along a stacking direction D. Moreover, each of the connection electrodes 230 may be aligned with the pixel electrode 130 along the stacking direction D.

In the present embodiment, the conductive particles 300A may contact the connection electrodes 230 and the pixel electrodes 130. The conductive particles 300A are distributed on a region where the pixel electrodes 130 overlap the connection electrodes 230 along the stacking direction D, without being distributed between a region K1 between the pixel electrodes 130 and a region K2 between the connection electrodes 230. The conductive particles 300A located on the same pixel electrode 130 contacts the pixel electrode 130 and one connection electrode 230 corresponding to the pixel electrodes 130 and conducts on each of the pixel electrodes 130 and one connection electrode 230 corresponding thereto. It is to be mentioned that conductive particles 300A may facilitate in reducing the resistivity between each of the pixel electrodes 130 and the corresponding connection electrode 230 so as to enhance the performance of the display panel 1000.

Additionally, the display panel 1000 of the present embodiment may selectively include the adhesive patterns 500 located between the conductive particles 300A and the pixel electrodes 130 or between the conductive particles 300A and the connection electrodes 230, but the present invention is not limited thereto. In other embodiments, if the adhesive patterns 500 are completely volatilized during the process of heating the conductive particles 300A, the display panel 1000 may also not include the adhesive patterns 500. The display panel 1000 of the present embodiment may selectively include a plurality of gap maintaining structures 400. The gap maintaining structures 400 are disposed between the active device substrate 100 and the display medium substrate 200. The gap maintaining structures 400 may facilitate in keeping the distance d between the active device substrate 100 and the display medium substrate 200 more consistent.

In the present embodiment, the pixel electrodes 130 may be reflective electrodes, and the second plate 210 may be a transparent substrate. The common electrode 240 locate d in the display medium substrate 200 may also be a transparent electrode. The light from the display medium layer 220 may be reflected by the pixel electrodes 130 and then emit through the second plate 210 and the common electrode 240. In other words, in the present embodiment, the light for displaying images does not have to pass through the active devices 120, and thus, the volume occupied by the active devices 120 would not influence the brightness of the display panel 1000, such that the design of the form of the active devices 120 may be more flexible. For example, the active devices 120 may adopt SCLTs with a large output current.

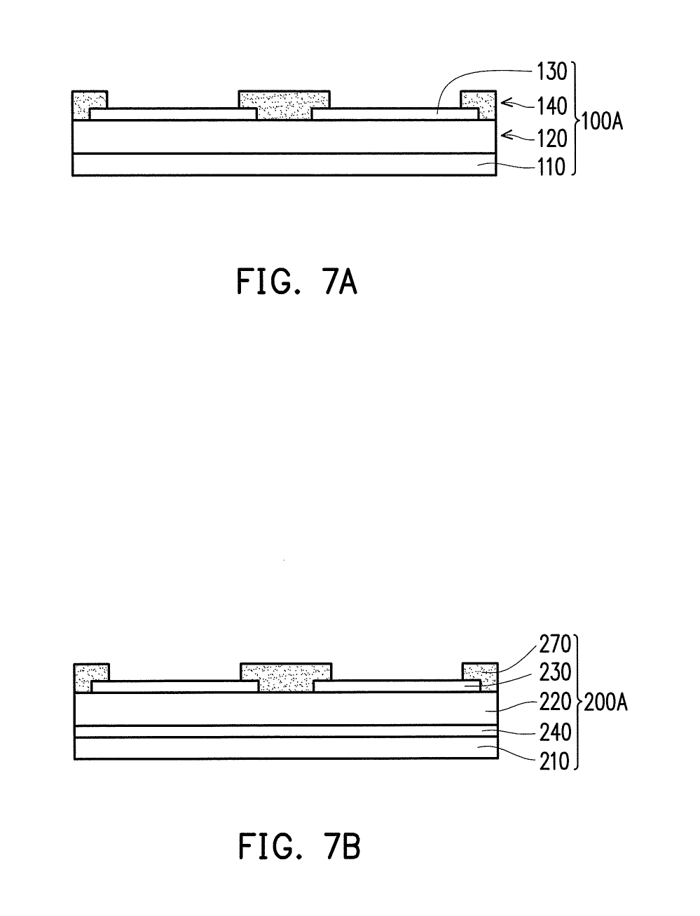

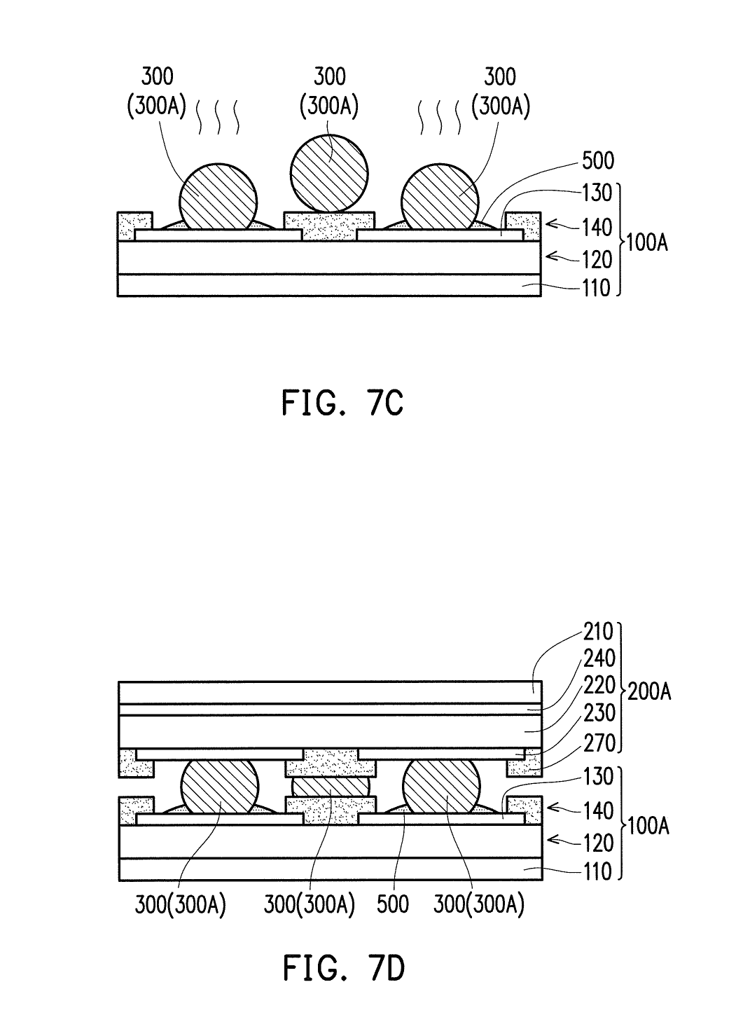

In the embodiment illustrated in FIG. 1A through FIG. 1G and FIG. 2A through FIG. 2E, the conductive particles 300A are distributed on specified positions by using the shielding mask 600. In order to simplify the manufacturing process of the display panel, the active device substrate 100 may further include a first insulation pattern layer, and the display medium substrate 200 may further include a second insulation pattern layer. Thereby, the step of distributing the conductive particles 300A on the specified positions by using the shielding mask 600 may be omitted, such that the manufacturing process of the display panel may be simpler, which will be specifically described with reference to FIG. 7A through FIG. 7D.

FIG. 7A through FIG. 7D are cross-sectional schematic diagrams illustrating a manufacturing process of a display panel according to an embodiment of the present invention. The manufacturing process of the display panel illustrated in FIG. 7A through FIG. 7D is similar to that illustrated in FIG. 1A through FIG. 1G, the same elements are labeled by the same or corresponding reference numerals. Referring to FIG. 7A and FIG. 7B, an active device substrate 100A and a display medium substrate 200A is provided. Referring to FIG. 7A, the active device substrate 100A is different from the active device substrate 100 in that the active device substrate 100A additionally has a first insulation pattern layer 140. The first insulation pattern layer 140 exposes the pixel electrodes 130 and covers a region K1 between the pixel electrodes 130 in the first plate 110. Referring to FIG. 7B, the display medium substrate 200A is different from the display medium substrate 200 in that the display medium substrate 200A additionally has a second insulation pattern layer 270. The second insulation pattern layer 270 exposes the connection electrodes 230 and covers a region K2 between the connection electrodes 230 in the second plate 210.

Referring to FIG. 7C, the conductive particles 300A are distributed on one the plurality of pixel electrodes 130 and the plurality of connection electrodes 230. In FIG. 7C, an example where the conductive particles 300A are distributed on the pixel electrodes 130 is exemplarily illustrated, however, the present invention is not limited thereto. In other embodiments, the conductive particles 300A ma also distributed on the connection electrodes 230. It is to be noticed that in the embodiment illustrated in FIG. 7A through FIG. 7D, the first insulation pattern layer 140 covers the region K1 between the pixel electrodes 130 in the first plate 110, and the second insulation pattern layer 270 covers the region K2 between the connection electrodes 230 in the second plate 210, and thus, when distributing the conductive particles 300A on the pixel electrodes 130 or the connection electrodes 230, the conductive particles 300A may be distributed only on the pixel electrodes 130 or only on the connection electrodes 230 without using the shielding mask 600. In other words, the conductive particles 300A may be distributed in any simple way, without the worry of distributing the conductive particles 300A on the region K1 between the pixel electrodes 130 or on the region K2 between the connection electrodes 230, and thereby, the short-circuit problem may be prevented.

Referring to FIG. 7C, the conductive particles 300A are heated such that the conductive particles 300A are in the melted state (i.e., the liquid state). Referring to FIG. 7D, then, when the conductive particles 300A are not completely transferred from the liquid state to the solid state, the display medium substrate 200 is placed on the conductive particles 300A such that each of the connection electrodes 230 of the display medium substrate 200 contact at least one conductive particle 300A on the corresponding pixel electrode 130. Thereby, when the temperature of the conductive particles 300A is lowered down to below the melting point of the conductive particles 300A, each of the connection electrodes 230 may be fixedly connected and conducted on with the corresponding pixel electrode 130. Up to this step, a display panel display panel 1000B is initially finished.

Referring to FIG. 7D, the display panel 1000B manufactured by the manufacturing method illustrated in FIG. 7A through FIG. 7D is similar to the display panel 1000. Therefore, the same elements are labeled by the same or corresponding numerals. The display panel 1000B is different from the display panel 1000 in that the display panel 1000B additionally has the first insulation pattern layer 140 located between the conductive particles 300A and the pixel electrodes 130 and the second insulation pattern layer 270 located between the conductive particles 300A and the connection electrodes 230. The display panel 1000B has not only the advantages of the display panel 1000 but also an advantage of being manufactured by a simple manufacturing process.

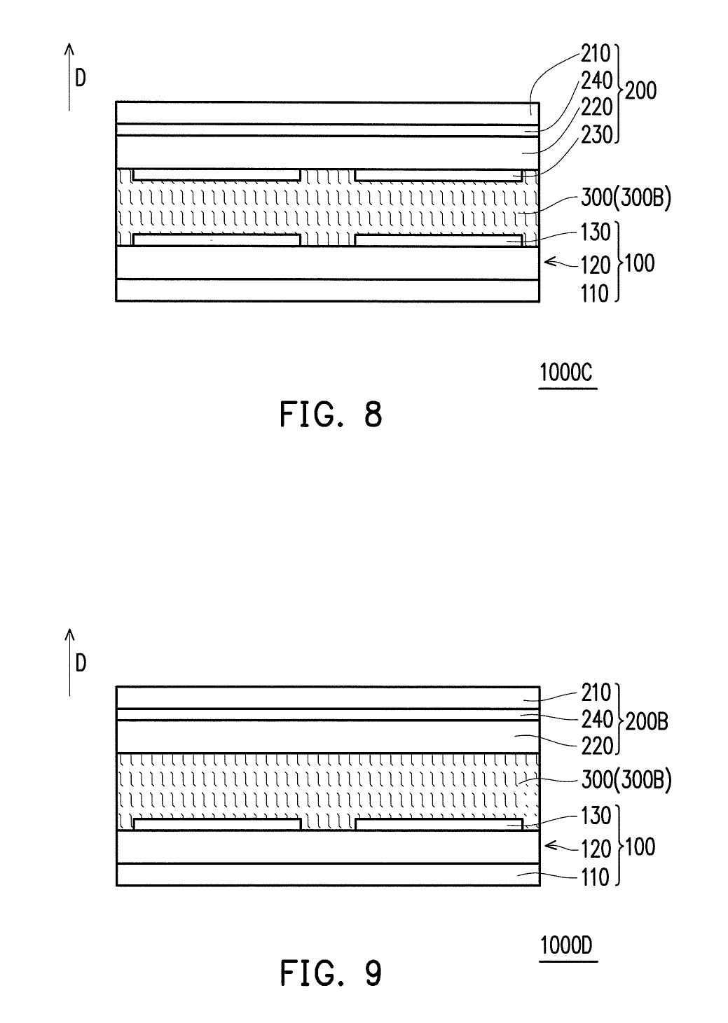

FIG. 8 is a cross-sectional schematic diagram illustrating a manufacturing process of a display panel according to an embodiment of the present invention. The display panel manufactured by the manufacturing process illustrated in FIG. 8 is similar to the display panel manufactured by the manufacturing process illustrated in FIG. 1A through FIG. 1G, and therefore, the same elements are labeled by the same or corresponding numerals. Referring to FIG. 8, the manufacturing process of the display panel illustrated in FIG. 8 is different from that illustrated in FIG. 1A through FIG. 1G in that the manufacturing process of the display panel illustrated in FIG. 8 adopts an ACF 300B which is electrically connected with the pixel electrodes 130 and the display medium layer 220, and thereby, the manufacturing process of the display panel is simpler. In detail, an active device substrate 100 and a display medium substrate 200 are provided. Then, the ACF 300B is formed on one of the plurality of pixel electrodes 130 and the plurality of display medium layer 220. Thereafter, the other one of the plurality of pixel electrodes 130 and the plurality of display medium layer 220 is connected with the ACF 300B. It is to be noticed that the ACF 300B has electrical conductivity along the stacking direction D of the active device substrate 100 overlapping the display medium substrate 200 but does not have the electrical conductivity in a direction perpendicular to the stacking direction D. Thus, in the present embodiment, the ACF 300B conducts on the pixel electrodes 130 with the corresponding connection electrodes 230, without causing the short-circuit problem between the pixel electrodes 130, between the connection electrodes 230 and between the pixel electrodes 130 and the connection electrodes 230 not corresponding thereto.

A display panel 1000C manufactured by the manufacturing method illustrated in FIG. 8 is different from the display panel 1000 manufactured by the manufacturing method illustrated in FIG. 1A through FIG. 1G in that the conductive material 300 of the display panel 1000C is the ACF 300B. In FIG. 8, the ACF 300B may contact the connection electrodes 230 and the pixel electrodes 130.

FIG. 9 is a cross-sectional schematic diagram illustrating a manufacturing process of a display panel according to an embodiment of the present invention. The manufacturing process of the display panel illustrated in FIG. 9 is similar to that illustrated in FIG. 8, and therefore, the same elements are labeled by the same or corresponding numerals. Referring to FIG. 9, the manufacturing process of the display panel illustrated in FIG. 9 is different from that illustrated in FIG. 8 in that a display medium substrate 200B adopted by the embodiment illustrated in FIG. 9 may not include the connection electrodes 230. The ACF 300B may contact the display medium layer 220 and the pixel electrodes 130. Similarly, a display panel 1000D manufactured by the manufacturing process illustrated in FIG. 9 has not only the advantages of the display panel 1000 but also the advantage of being manufactured by a simple manufacturing process.

To sum up, in the display panel manufacturing method and the display panel manufactured thereby according to one of the embodiments of the present invention, the pixel electrodes are electrically connected with the display medium layer by using the conductive material. Thus, the resistivity between the pixel electrodes and the display medium layer is small, such that the display panel has good performance.

Additionally, in the display panel manufacturing method according to one of the embodiments of the present invention, the size of the conductive particles may be larger than the maximum change of the thickness of the display medium substrate or the maximum change of the thickness of the active device substrate. By doing so, when the connection electrodes are about to be electrically connected with the pixel electrodes 130 in a follow-up step, the conductive particles may compensate the height difference between the connection electrodes or between the pixel electrodes such that each of the pixel electrodes may be electrically connected with the corresponding connection electrode well to enhance the yield of the display panel.

Moreover, in the display panel manufacturing method according to one of the embodiments of the present invention, the light from the display medium layer may be reflected by the pixel electrodes to emit to the display panel through the second plate. Thus, the active devices located under the display medium layer would not influence the brightness of the display panel, and the design of the form of the active devices 120 may be more flexible, such that the display panel has better electrical and optical characteristics.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A manufacturing method of a display panel, comprising:
providing an active device substrate, wherein the active device substrate comprises a first plate, a plurality of active devices disposed on the first plate and a plurality of pixel electrodes electrically connected to the plurality of active devices;
providing a display medium substrate, wherein the display medium substrate comprises a second plate and a display medium layer disposed on the second plate; and
electrically connecting the plurality of pixel electrodes with the display medium layer by using a conductive material.

2. The method as recited in claim 1, wherein the conductive material comprises a plurality of conductive particles.

3. The method as recited in claim 2, wherein the display medium substrate further comprises a plurality of connection electrodes corresponding to the plurality of pixel electrodes, the display medium layer is located between the second plate and the plurality of connection electrodes, and the step of electrically connecting the plurality of pixel electrodes with the display medium layer by using the conductive material comprises:
distributing the plurality of conductive particles on the plurality of pixel electrodes and electrically insulating at least one conductive particle of the plurality of conductive particles distributed on the same pixel electrode from the other conductive particles;
heating the plurality of conductive particles; and
contacting each of the plurality of connection electrodes with the at least one conductive particle on the corresponding pixel electrodes.

4. The method as recited in claim 3, wherein the step of distributing the plurality of conductive particles on the plurality of pixel electrodes and electrically insulating the at least one conductive particle distributed on the same pixel electrode from the other conductive particles comprises:
providing a mask, wherein the shielding mask has a shielding portion and a plurality of through holes penetrating through the shielding portion;
exposing the plurality of pixel electrodes respectively from the plurality of through holes of the shielding mask and shielding a region between the plurality of pixel electrodes by the shielding portion of the mask; and
penetrating the plurality of conductive particles through the plurality of through holes by using the shielding mask so as to distribute the same on the plurality of pixel electrodes.

5. The method as recited in claim 3, wherein before the step of distributing the plurality of conductive particles on the plurality of pixel electrodes, the method further comprises a step of forming a plurality of adhesive patterns on the plurality of pixel electrodes,
wherein the step of distributing the plurality of conductive particles on the plurality of pixel electrodes comprises fastening the plurality of conductive particles on the plurality of pixel electrodes through the plurality of adhesive patterns.

6. The method as recited in claim 5, wherein a material of the plurality of adhesive patterns is flux.

7. The method as recited in claim 2, wherein the display medium substrate further comprises a plurality of connection electrodes corresponding to the plurality of pixel electrodes, the display medium layer is located between the second plate and the plurality of connection electrodes, and the step of electrically connecting the plurality of pixel electrodes with the display medium layer by using the conductive material comprises:
distributing the plurality of conductive particles on the plurality of connection electrodes and electrically insulating at least one conductive particle of the plurality of conductive particles distributed on the same connection electrode from the other conductive particles;
heating the plurality of conductive particles; and
contacting of contacting each of the plurality of connection electrodes with the at least one conductive particle on the corresponding connection electrode.

8. The method as recited in claim 7, wherein the step of distributing the plurality of conductive particles on the plurality of connection electrodes and electrically insulating the at least one conductive particle of the plurality of conductive particles distributed on the same connection electrode from the other conductive particles comprises:
providing a mask, wherein the shielding mask has a shielding portion and a plurality of through holes penetrating through the shielding portion;
exposing the plurality of connection electrodes from the plurality of through holes of the shielding mask and shielding a region between the plurality of pixel electrodes by the shielding portion of the mask; and
penetrating the plurality of conductive particles through the plurality of through holes by using the shielding mask so as to distribute the same on the plurality of connection electrodes.

9. The method as recited in claim 7, wherein before the step of distributing the plurality of conductive particles on the plurality of connection electrodes, the method further comprises a step of forming a plurality of adhesive patterns on the plurality of connection electrodes, and
wherein the step of distributing the plurality of conductive particles on the plurality of connection electrodes comprises fastening the plurality of conductive particles on the plurality of connection electrodes through the plurality of adhesive patterns.

10. The method as recited in claim 9, wherein a material of the plurality of adhesive patterns is flux.

11. The method as recited in claim 2, wherein a size of each of the plurality of conductive particles is larger than a maximum change of a thickness of the active device substrate or a maximum change of a thickness of display medium substrate.

12. The method as recited in claim 2, wherein
the active device substrate further comprises a first insulation pattern layer, wherein the first insulation pattern layer exposes the plurality of pixel electrodes and covers a region between the plurality of pixel electrodes in the first plate,
the display medium substrate further comprises a second insulation pattern layer, wherein the second insulation pattern layer exposes the plurality of connection electrodes and covers a region between the plurality of connection electrodes in the second plate, and
the step of electrically connecting the plurality of pixel electrodes with the display medium layer by using the conductive material comprises:
distributing the plurality of conductive particles on one of the plurality of pixel electrodes and the plurality of connection electrodes;
heating the plurality of conductive particles; and
contacting the other one of the plurality of pixel electrodes and the plurality of connection electrodes with the plurality of conductive particles.

13. The method as recited in claim 1, wherein the conductive material is an anisotropic conductive film (ACF), and the step of electrically connecting the plurality of pixel electrodes with the display medium layer by using the conductive material comprises:
forming the ACF on one of the plurality of pixel electrodes and the display medium layer; and
connecting the other one of the plurality of pixel electrodes and the display medium layer with the ACF.

14. The method as recited in claim 1, wherein before the step of electrically connecting the plurality of pixel electrodes with the display medium layer by using the conductive material, the method further comprises a step of forming a plurality of gap maintaining structures on the active device substrate or the display medium substrate.

15. The method as recited in claim 1, wherein before the step of electrically connecting the plurality of pixel electrodes with the display medium layer by using the conductive material, the method further comprises a step of performing an annealing process on the active device substrate.

16. A display panel, comprising:
an active device substrate, comprising:
a first plate;
a plurality of active devices, disposed on the first plate; and
a plurality of pixel electrodes, electrically connected with the plurality of active devices;
a display medium substrate, being opposite to the active device substrate and comprising:
a second plate; and
a display medium layer, disposed on the second plate;
a conductive material, disposed between the display medium layer and the plurality of pixel electrodes and electrically connecting the plurality of pixel electrodes with display medium layer.

17. The display panel as recited in claim 16, wherein the conductive material comprises a plurality of conductive particles, the display medium substrate further comprises a plurality of connection electrodes corresponding to the plurality of pixel electrodes, the display medium layer is located between the second plate and the plurality of connection electrodes, and the plurality of conductive particles contacts the plurality of connection electrodes and the plurality of pixel electrodes.

18. The display panel as recited in claim 17, wherein the plurality of conductive particles are distributed on a region where the plurality of pixel electrodes overlaps the plurality of connection electrodes, but neither distributed on a region between the plurality of pixel electrodes nor a region between the plurality of connection electrodes.

19. The display panel as recited in claim 17, wherein the active device substrate further comprises a first insulation pattern layer, the plurality of pixel electrodes is located between the first insulation pattern layer and the first plate, the first insulation pattern layer exposes the plurality of pixel electrodes and covers a region between the plurality of pixel electrodes in the first plate, the display medium substrate further comprises a second insulation pattern layer, the plurality of connection electrodes is located between the second plate and the second insulation pattern layer, the second insulation pattern layer exposes the plurality of connection electrodes and covers a region between the plurality of connection electrodes in the second plate.

20. The display panel as recited in claim 16, wherein the conductive material is an anisotropic conductive film (ACF) contacting the display medium layer and the plurality of pixel electrodes.

21. The display panel as recited in claim 20, wherein the display medium substrate further comprises a plurality of connection electrodes corresponding to the plurality of pixel electrodes and is located between the second plate and the plurality of connection electrodes, and the ACF contacts the plurality of connection electrodes.

22. The display panel as recited in claim 16, further comprising:
a plurality of gap maintaining structures, disposed between the active device substrate and the display medium substrate.

23. The display panel as recited in claim 16, wherein the display medium substrate further comprises a common electrode located between the second plate and the display medium layer.

24. The display panel as recited in claim 23, wherein the pixel electrodes are reflective electrodes, the common electrode is a transparent electrode, and the second plate is a transparent substrate.

25. The display panel as recited in claim 16, wherein the pixel electrodes are reflective electrodes, and the second plate is a transparent substrate.
